(19) United States
(12) Patent Application Publication
(10) Pub. No.: US 2012/0154009 A1
(43) Pub. Date: Jun. 21, 2012

(54) LATCH CIRCUITRY

(75) Inventor: Chen-Kang HO, Hsinchu (TW)

(73) Assignee: TAIWAN SEMICONDUCTOR MANUFACTURING COMPANY, LTD., Hsinchu (TW)

(21) Appl. No.: 12/968,540

(22) Filed: Dec. 15, 2010

(51) Int. Cl. H03K 3/00

(52) U.S. Cl. 327/215

(57) ABSTRACT

A latch circuit comprises: a cross latch having a first node and a second node, a first transistor, a second transistor, a third transistor, a first current source, and a second current source. A third terminal of the first transistor and of the second transistor receives a first input signal and a second input signal, respectively. A first terminal of the first transistor and of the second transistor is coupled to the first node and the second node, respectively. A first terminal of the third transistor is coupled to the second terminal of the first transistor and of the second transistor. The first current source is coupled to the first node and affects a transition of a first output signal. The second current source is coupled to the second node and affects a transition of a second output signal.

### FIELD

The present disclosure is related to latch circuitry.

### BACKGROUND

Current-mode logic and injection-locked type circuits used in latches are widely run at high speed or high frequency, e.g., in the Giga Hertz (GHz) range. In those circuits, however, the signal amplitudes are sacrificed for the desired speed to be achieved. The operational swing is reduced, i.e., not rail-to-rail. Further, in many applications, the circuits may require a high power amplifier or buffer to boost the output signal to a rail-to-rail swing.

### BRIEF DESCRIPTION OF THE DRAWINGS

The details of one or more embodiments of the disclosure are set forth in the accompanying drawings and the description below. Other features and advantages will be apparent from the description, drawings, and claims.

FIG. 1 is a diagram of a latch circuit, in accordance with a first embodiment.

FIG. 2 is a diagram of a latch circuit, in accordance with a second embodiment.

FIG. 3 is a diagram of a latch circuit, in accordance with a third embodiment.

FIG. 4 is a diagram of a latch circuit, in accordance with a fourth embodiment.

FIG. 5 is a diagram of a master-slave D-type flip-flop that uses two latches in FIG. 1, in accordance with some embodiments.

FIG. 6 is a diagram of a frequency divider that uses two latches in FIG. 1, in accordance with some embodiments.

FIG. 7 is a flowchart illustrating a method of operating the latch circuit in FIG. 1, in accordance with some embodiments.

FIG. 8 is a flowchart illustrating a method of operating the latch circuit in FIG. 3, in accordance with some embodiments.

Like reference symbols in the various drawings indicate like elements.

### DETAILED DESCRIPTION

Embodiments, or examples, illustrated in the drawings are disclosed below using specific language. It will nevertheless be understood that the embodiments and examples are not intended to be limiting. Any alterations and modifications in the disclosed embodiments, and any further applications of the principles disclosed in this document are contemplated as would normally occur to one of ordinary skill in the pertinent art. Reference numbers may be repeated throughout the embodiments, but they do not require that feature(s) of one embodiment apply to another embodiment, even if they share the same reference number.

Some embodiments have one or a combination of the following features and/or advantages. A latch in accordance with some embodiments operates in a wide frequency range, including, for example, a high frequency range from about 20 GHz down to about 10 MHz range. The high frequency latch enables high frequency applications such as D flip-flops, frequency dividers, and frequency synthesizers, including, for example, phase-lock loop (PLL) circuits, delayed-lock loop (DLL) circuits, clock and data recovery (CDR) circuits, etc. In some embodiments, when the clock is on, the output transition is pulled up or pulled down faster, resulting in higher frequency operations. When the clock is off, however, the current leakage path is cut off. As a result, the leakage current is reduced and the latch is able to operate at lower frequencies. Output of the latch is a full rail-to-rail swing, and the latch consumes low power.

### Latch Circuit—First Embodiments

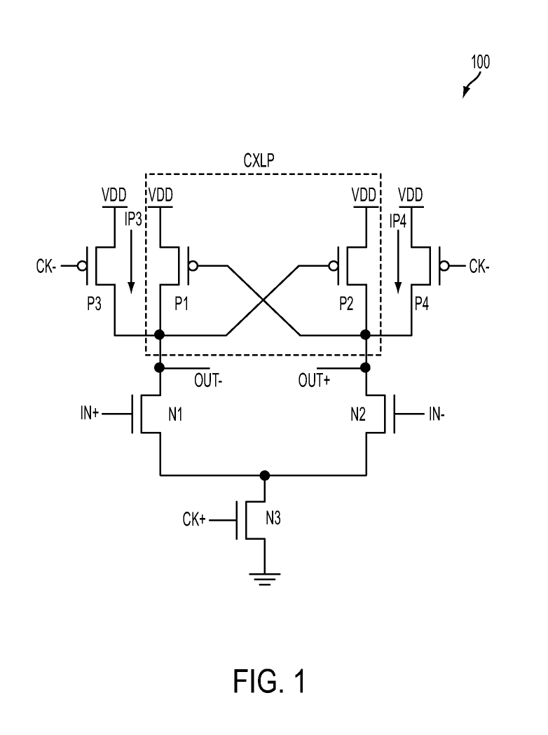

FIG. 1 is a diagram of an exemplary latch or latch circuit 100, in accordance with some embodiments. Latch circuit 100 is commonly called a dynamic latch. Because latch 100 is symmetrical, the operation on one side of latch 100 is similar to the operation on the other side of latch 100. For example, the operation on signal IN+ with respect to N-type Metal-Oxide Semiconductor (NMOS) transistor N1, P-type Metal-Oxide Semiconductor (PMOS) transistor P1, PMOS transistor P3, and signal OUT− is similar to the operation on signal IN− with respect to NMOS transistor N2, PMOS transistor P2, PMOS transistor P4, and signal OUT+, respectively. As a result, for simplicity, the operation on only one side of latch 100 is described in this document, and the operation on the other side is recognizable by persons of ordinary skill in the art.

Transistors P1 and P2 form cross latch CXLP. The gate of transistor P1 is coupled to the drain of transistor P2 while the gate of transistor P2 is coupled to the drain of transistor P1. When transistor N3 is on, transistors N1 and N2 serve as a pull-down circuit for signal OUT− and signal OUT+, respectively.

Nodes NIN+ and NIN− (not labeled) are configured to receive input signals IN+ and IN−, respectively. Signals IN+ and IN−, driven to the gate of respective transistors N1 and N2, are differential signals. For example, when signal IN+ is at a high logic level (High), signal IN− is at a low logic level (Low), and when signal IN+ is Low, signal IN− is High.

Nodes NCK+ and NCK− (not labeled) are configured to receive clock signals CK+ and CK−, respectively. Signal CK+ driven to the gate of transistor N3 and signal CK− driven to the gates of transistors P3 and P4 are also differential signals. For illustration, signals CK+ and CK− are referred to as part of a clock, e.g., clock CLK, not labeled. Further, clock CLK is “on” when signal CK+ is High and signal CK− is Low, and clock CLK is off when signal CK+ is Low and signal CK− is High. In some embodiments, when clock CLK is on, the inverse of signal IN+ and signal IN− is transferred to signal OUT− and OUT+, respectively. In other words, when clock CLK is on, signal OUT− and signal OUT+ are inverted signals of the respective signals IN+ and IN−. If, however, clock CLK is off, signal OUT− and signal OUT+, in some embodiments, remain at their previous logic levels based on parasitic capacitance at respective nodes NOUT− and NOUT+ and of the feature of a dynamic latch that functions at high frequencies, regardless of the respective signals IN+ and IN−. For example, when clock CLK is off, signal CK+ driven at the gate of transistor N3 is Low. Transistor N3 is therefore off, and transistors N1 and N2 act as open circuits. If signal OUT− is Low, then signal OUT+ is High. Further, because signal OUT− is driven at the gate of transistor P2, which is Low, transistor P2 is turned on, pulling signal OUT+ to voltage VDD at the source of transistor P2, which is High. At the same time, transistor P1 is off, acting as an open circuit. In effect, signal OUT− remains at its existing low level. In contrast, if signal OUT− is High, signal OUT+ is Low, which turns on transistor P1. Consequently, signal OUT− is pulled up the voltage level at the source of transistor P1, which is VDD or High. In effect, signal OUT− remains at its existing high level.

Nodes NOUT+ and NOUT− (not labeled) serve as outputs for latch 100 and provide output signals OUT+ and OUT−, respectively. In some embodiments, signal OUT− and signal OUT+ are the inverse of signal IN+ and signal IN−, respectively. For example, when clock CLK is on, i.e., signal CK+ is High (and signal CK− is Low), transistor N3 is on. If signal IN+ at the gate of transistor N1 is High, transistor N1 is turned on. Transistor N1 and transistor N3 being on pull the voltage level of signal OUT− towards the voltage level at the source of transistor N3, which is ground or Low, and which is also the inverse of signal IN+. But if signal IN+ at the gate of transistor N1 is Low, transistor N1 is turned off. As a result, transistors N1 and N3 act as open circuits, and the voltage level of signal OUT− at the drains of transistors N1, P1, and P3 is pulled towards the operational voltage VDD at the source of transistor P1 and transistor P3, which is High, and which is also the inverse of signal IN+.

Transistors P3 and P4 serve as current sources, and, in effect, provide respective currents IP3 and IP4 to help respective transistors P1 and P2 pull up respective signals OUT− and OUT+ faster. For example, initially, signal IN+ at the gate of transistor N1 is High, transistor N1 is on, and signal OUT− is Low. Signal IN+ at the gate of transistor N1 then transitions from a High to a Low. As a result, transistor N1 is turned off, signal OUT− is pulled up to the level at the source of transistor P1, which is voltage VDD. Transistor P3 coupled in parallel with transistor P1 and having signal OUT− at its drain also pulls signal OUT− to the source of transistor P3, which is also voltage VDD. In effect, signal OUT− is pulled up to voltage VDD by both transistor P1 and transistor P3. As a result, signal OUT− is pulled up to voltage VDD faster than signal OUT− being pulled up by just one transistor P1. In other words, transistor P3 causes signal OUT− to transition from a Low to a High faster than a configuration without transistor P3. Similarly, transistor P4 causes signal OUT+ to transition from a Low to a High faster than a configuration without transistor P4.

In some embodiments, without the existence of transistors P3 and P4, latch 100 fails to function in the 20 GHz range because signal OUT− and signal OUT+ cannot switch as fast as the switching of the respective signal IN+ and IN−. Transistors P3 and P4 help widen the operational range of latch 100 to function in the 20 GHz because transistor P3 causes signal OUT− to transition from a Low to a High faster and transistor P4 causes signal OUT+ to transition from a Low to a High faster. In some embodiments, the operational frequency for latch 100 is determined by the size of transistor P3 and P4. For example, with respect to transistor P3, signal OUT− is observed and, for illustration, latch 100 functions properly. The size of transistor P3 is then adjusted until signal OUT− starts to distort or fail to have appropriate voltage levels. For another example, when clock CLK is on, signal OUT− is the inverse of signal IN+, and latch 100 fails to function properly when signal OUT− fails to be the inverse of signal IN+. Similarly, when clock CLK is off, signal OUT− is to remain at its previous level, and latch 100 fails to function properly when signal OUT− starts to shift its level, etc. At the time signal OUT− fails to have an appropriate level, which indicates latch 100 fails to function properly, the size of transistor P3 is selected. In some embodiments, selecting the size for transistor P3 and thus current IP3 depends on the trade off between speeding up the transition of signal OUT− from a Low to a High for operating at a predetermined operating frequency, the die area to manufacture transistor P3, and the power consumed by transistor P3. For example, the larger the current IP3 results in the faster the transition from a Low to a High for signal OUT−, but the larger the size transistor P3 and thus the larger the die area, and the higher the power consumed by transistor P3. In contrast, the smaller the size of transistor P3 results in the smaller the die area and the smaller the power consumed by transistor P3, but the slower the transition for signal OUT− from a Low to a High. In some embodiments, an amount of increased speed in the transition for signal OUT− is determined and the size of transistor P3 is selected accordingly. Selecting the size for transistor P4 is similar to selecting the size for transistor P3.

In some embodiments, when clock CLK is off, there is no leakage current from transistor P3 and transistor P4 because, at that time, signal CK− at the gates of transistors P3 and P4 is High, causing both transistors P3 and P4 to be off. At the same time, signal CK+ driven at the gate of transistor N3 is Low and causes transistor N3 to be off. Consequently, there is no current path through transistor N3 to ground for latch 100. In other words, when clock CLK is off, the current leakage path for latch 100 is cut off, and the current leakage is reduced or eliminated. Because the leakage current is reduced or eliminated, latch 100 is able to operate at lower frequencies, e.g., in the 10 MHz range because, in some embodiments, the leakage current causes signal OUT− and signal OUT+ to shift levels and thus prevents latch 100 to operate in the 10 MHz range.

In some embodiments, adding transistors P3 and P4 to latch 100 improves the operational frequency of latch 100 by about 30%, but transistors P3 and P4 consume insignificant power in latch 100 as a whole. In the above description, transistors P3 and P4 are used for illustration, mechanisms that provide the current to respective nodes NOUT− and NOUT+ of signals OUT− and OUT+ to help speed up the transition of signal OUT− and signal OUT+ are within the scope of various embodiments. For example, a current source is used in place of transistor P3 and/or transistor P4. Further, the current source is turned off when clock CLK is off. A switching mechanism is used to turn on/off the current source.

### Latch Circuit—Second Embodiments

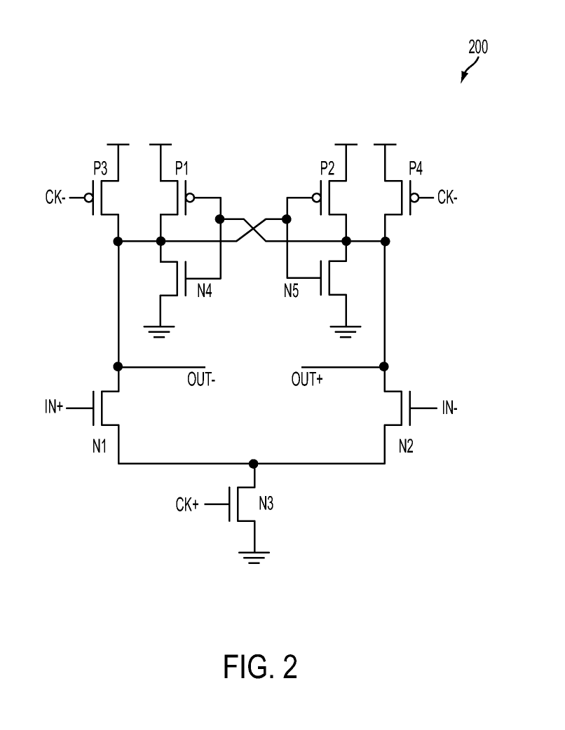

FIG. 2 is a diagram of a latch or latch circuit 200, in accordance with some embodiments. Compared with latch 100, latch 200 includes additional NMOS transistors N4 and N5. Latch circuit 200 is commonly called a static latch. The drain of transistor N4 is coupled to node NOUT− of signal OUT−, which is also the drains of transistor P1, transistor P3, and transistor N1, and the gates of transistors P2 and N5. The source of transistor N4 is coupled to ground. The gate of transistor N4 is coupled to the gate of transistor P1, which is also the drains of transistor P2, transistor P4, and transistor N5. The drain of transistor N5 is coupled to the node of signal OUT+, which is also the drains of transistor P2, transistor P4, and transistor N2, and the gates of transistor P1 and transistor N4. The source of transistor N5 is coupled to ground. The gate of transistor N5 is coupled to the gate of transistor P2, which is also the drains of transistor P1, transistor P3, and transistor N4.

Similarly to latch 100, transistor P3 and transistor P4 help speed up the transition of signal OUT− and signal OUT+, respectively.

### Latch Circuit—Third Embodiments

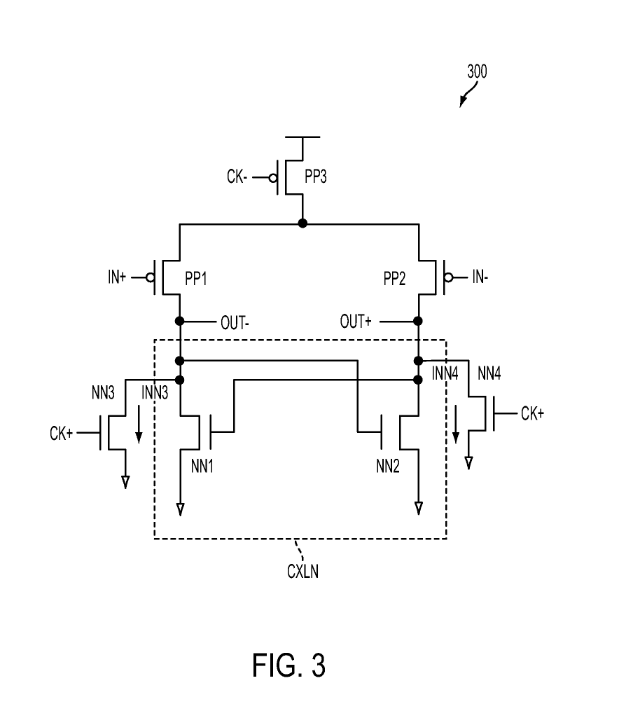

FIG. 3 is a diagram of a latch circuit 300, in accordance with some embodiments. Latch circuit 300 is commonly called a dynamic latch. NMOS transistors NN1 and NN2 form cross latch CXLN. When PMOS transistor PP3 is on, PMOS transistors PP1 and PP2 serve as a pull-up circuit for signal OUT− and signal OUT+, respectively.

Similarly to circuit 100, signals IN+ and IN− driven to the gates of respective transistors PP1 and PP2 are differential signals. When signal IN+ is High, signal IN− is Low, and when signal IN+ is Low, signal IN− is High.

Signal CK− is driven to the gate of transistor PP3, and signal CK+ is driven to the gates of NMOS transistors NN3 and NN4. Similarly to circuit 100, in some embodiments, when clock CLK is on, the inverse of signal IN+ and signal IN− is transferred to signal OUT− and OUT+, respectively. In other words, when clock CLK is on, signal OUT− and signal OUT+ are inverted from the respective signals IN+ and IN−. For example, when clock CLK is on, i.e., signal CK− at the gate of transistor PP3 is Low, transistor PP3 is on. If signal IN+ at the gate of transistor PP1 is Low, transistor PP1 is on. Transistor PP1 and transistor PP3 being on pull the voltage level of signal OUT− towards the voltage level at the source of transistor PP3, which is voltage VDD or High, and which is also the inverse of signal IN+. But if signal IN+ at the gate of transistor PP1 is High, transistor PP1 is off. As a result, transistor PP1 acts as an open circuit. At the same time, signal IN− at the gate of transistor PP2 is Low, which turns on transistor PP2. Transistors PP2 and PP3 being on pull signal OUT+ at the drain of transistor PP2 to the source of transistor PP3, which High. As a result, transistor NN1 is on. Because signal CK+ at the gate of transistor NN3 is High, transistor NN3 is on. Transistors NN1 and NN3 being on pull signal OUT− at the drains of transistors NN1 and NN3 to ground at the sources of transistor NN1 and transistor NN3, which is Low, and which is also the inverse of signal IN+.

If, however, clock CLK is off, signal OUT− and signal OUT+, in some embodiments, remain at their previous logic levels based on parasitic capacitance at respective nodes NOUT− and NOUT+ and of the feature of a dynamic latch that functions at high frequencies, regardless of the respective signals IN+ and IN−. For example, because clock CLK is off, signal CLK−at the gate of transistor PP3 is High, which causes transistor PP3 to turn off. As a result, transistors PP1 and PP2 act as open circuits. If signal OUT− at the gate of transistor NN2 is Low, then transistor NN2 is off, and signal OUT+ is High. Because signal OUT+ at the gate of transistor NN1 is High, transistor NN1 is on, which pulls signal OUT− at the drain of transistor NN1 to the source of transistor NN1, which is ground or Low. In effect, signal OUT− remains at the Low level, regardless of input signal IN+. If, however, signal OUT− is high, signal OUT+ at the gate of transistor NN1 is Low, which causes transistor NN1 to turn off and act as an open circuit. Because transistor PP1 and transistor NN1 act as an open circuit, signal OUT− remains at its High level. In effect, signal OUT− remains at the High level, regardless of input signal IN+.

Transistors NN3 and NN4 serve as current sources, and, in effect, provide respective currents INN3 and INN4 to help respective transistors NN1 and NN2 to pull down respective signals OUT− and OUT+ faster. For example, initially, signal IN+ at the gate of transistor PP1 is Low, transistor PP1 is on, and signal OUT− is High. Signal IN+ at the gate of transistor PP1 then transitions from a Low to a High. As a result, transistor PP1 is turned off, and signal OUT− at the drain of transistor NN1 is pulled down to the voltage level at the source of transistor NN1, which is ground. Transistor NN3 coupled in parallel with transistor NN1 and having signal OUT− at its drain also pulls signal OUT− to the source of transistor NN3, which is also ground. In effect, signal OUT− is pulled down to ground by both transistor NN1 and transistor NN3. As a result, signal OUT− is pulled down to ground faster than signal OUT− being pulled down by just one transistor NN1. In other words, transistor NN3 causes signal OUT− to transition from a High to a Low faster than a configuration without transistor NN3. Similarly, transistor NN4 causes signal OUT+ to transition from a High to a Low faster than a configuration without transistor NN4.

In some embodiments, without the existence of transistors NN3 and NN4, latch 300 fails to function in the 20 GHz range because signal OUT− and signal OUT+ cannot switch as fast as the switching of respective signals IN+ and IN−. Transistors NN3 and NN4 help widen the operational range of latch 300 to function in the 20 GHz because transistor NN3 causes signal OUT− to transition from a High to a Low faster and transistor NN4 causes signal OUT+ to transition from a High to a Low faster. In some embodiments, the operational frequency for latch 300 is determined by the sizes of transistors NN3 and NN4. For example, with respect to transistor NN3, signal OUT−is observed and, for illustration, latch 300 functions properly. The size of transistor NN3 is then adjusted until signal OUT− starts to distort or fail to have an appropriate voltage level. For another example, when clock CLK is on, signal OUT− is the inverse of signal IN+, and latch 300 fails to function properly when signal OUT− fails to be the inverse of signal IN+. Similarly, when clock CLK is off, signal OUT− should remain at its previous level, and latch 300 fails to function properly when signal OUT− starts to shift its level, etc. At the time signal OUT− fails to have the appropriate voltage level, which indicates latch 300 fails to function properly, the size of transistor NN3 is selected. In some embodiments, selecting the size for transistor NN3 and thus current INN3 depends on the trade off between speeding up the transition of signal OUT− from a High to a Low for operating at a predetermined operating frequency, the die area to manufacture transistor NN3, the power consumed by transistor NN3. For example, the larger the current INN3 results in the faster the transition from a High to a Low for signal OUT−, but the larger the size transistor NN3 and thus the larger the die area, and the higher the power consumed by transistor NN3. In contrast, the smaller the size of transistor NN3 results in the smaller the die area and the smaller the power consumed by transistor NN3, but the slower the transition from a High to a Low for signal OUT−. In some embodiments, an amount of increased speed in the transition for signal OUT− is determined and the size of transistor NN3 is selected accordingly. Selecting the size for transistor NN4 is similar to selecting the size for transistor NN3.

In some embodiments, when clock CLK is off, signal CK+ driven at the gates of transistor NN3 and transistor NN4 is Low and causes transistor NN3 and transistor NN4 to be off. As a result, there is no leakage current from transistor NN3 and transistor NN4. At the same time, when clock CLK is off, signal CK− at the gate of transistor PP3 is High, causing transistor PP3 to be off and act as an open circuit. Consequently, transistors PP1 and PP2 also act as open circuits, and do not generate leakage currents. In other words, when clock CLK is off, the current leakage path for latch 300 is cut off, and the leakage current is reduced or eliminated. As the leakage current is reduced or eliminated, latch 300 is able to operate at lower frequencies, e.g., in the 10 MHz range because, in some embodiments, the leakage current causes signal OUT− and signal OUT+ to shift levels and thus prevents latch 300 from operating in the 10 MHz range. In some embodiments, adding transistors NN3 and NN4 to latch 300 improves the operational frequency of latch 300 by about 30%, but transistors NN3 and NN4 consume insignificant power in latch 300 as a whole.

In the above description, transistors NN3 and NN4 are used for illustration, mechanisms that provide currents to the respective nodes NOUT− and NOUT+ of signals OUT− and OUT+ to help speed up the transition of signal OUT− and signal OUT+ are within the scope of various embodiments. For example, a current source is used in place of transistor NN3 and/or transistor NN4. Further, the current source is turned off when clock CLK is off. A switching mechanism is used to turn on/off the current source.

### Latch Circuit—Fourth Embodiments

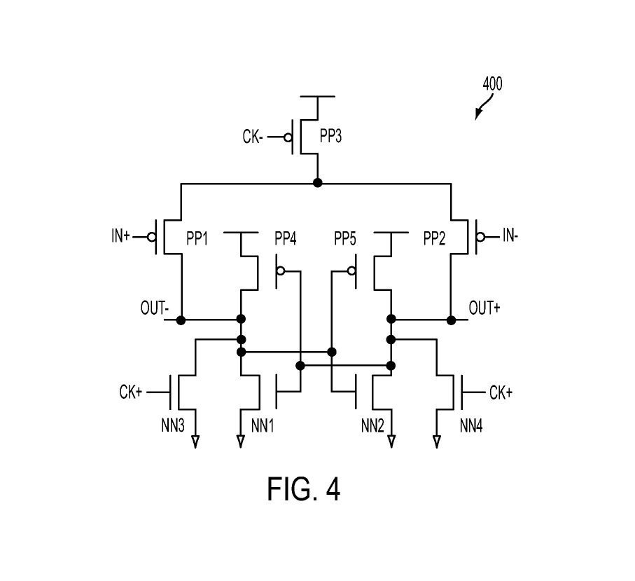

FIG. 4 is a diagram of a latch or latch circuit 400, in accordance with some embodiments. Compared with latch 300, latch 400 includes additional PMOS transistors PP4 and PP5. Latch circuit 400 is commonly called a static latch. The drain of transistor PP4 is coupled to node NOUT− of signal OUT−, which is also the drains of transistors NN1, NN3 and PP1, and the gates of transistors NN2 and PP5. The source of transistor PP4 is coupled to voltage VDD. The gate of transistor PP4 is coupled to the gate of transistor NN1, which is also the drains of transistors NN2, NN4, PP2, and PP5. The drain of transistor PP5 is coupled to node NOUT+ of signal OUT+, which is also the drains of transistors NN2, NN4 and PP2 and the gates of transistors NN1 and PP4. The source of transistor PP5 is coupled to voltage VDD. The gate of transistor PP5 is coupled to the gate of transistor NN2, which is also the drains of transistors PP1, PP4, NN3, and NN1.

Similarly to circuit 300, transistor NN3 and transistor NN4 help speed up the transition of signal OUT− and signal OUT+, respectively.

### Master-Slave D Flip-Flop

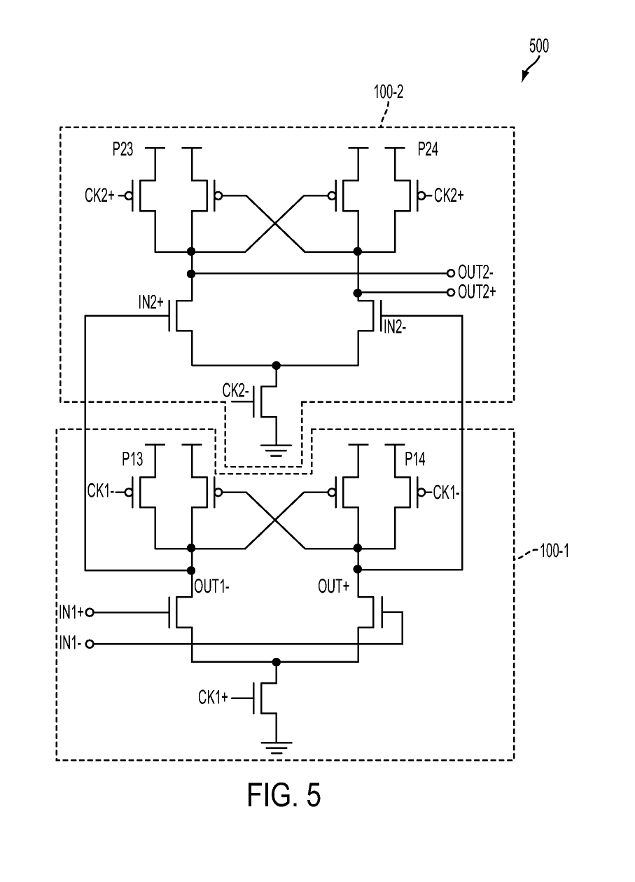

FIG. 5 is a diagram of a master-slave D flip-flop 500, in accordance with some embodiments. Flip-flop 500 includes two latches 100, e.g., latch 100-1 and latch 100-2. For simplicity, only PMOS transistors P13, P14, P23, and P24 in flip-flop 500 are labeled. Latch 100-1 includes input nodes NIN1+, NIN1− (not labeled), output nodes NOUT1+ and NOUT1− (not labeled), and clock nodes NCK1+ and NCK1− (not labeled) corresponding to input nodes NIN+, NIN−, output nodes NOUT+ and NOUT−, and clock nodes NCK+ and NCK− of latch 100, respectively. Similarly, latch 100-2 includes input nodes NIN2+, NIN2− (not labeled), output nodes NOUT2+ and NOUT2− (not labeled), and clock nodes NCK2+ and NCK2− (not labeled) corresponding to input nodes NIN+, NIN−, output nodes NOUT+ and NOUT−, and clock nodes NCK+ and NCK− of latch 100, respectively.

Input nodes NIN1+ and NIN1− are configured to receive respective input signals IN1+ and IN1−. Clock nodes NCK1+ and NCK1− are configured to receive respective clock signals CK1+ and CK1−. Output nodes NOUT1+ and NOUT1− are configured to provide respective output signals OUT1+ and OUT1−. Similarly, input nodes NIN2+ and NIN2− are configured to receive respective input signals IN2+ and IN2−. Clock nodes NCK2+ and NCK2− are configured to receive respective clock signals CK2+ and CK2−. Output nodes NOUT2+ and NOUT2− are configured to provide respective output signals OUT2+ and OUT2−.

Nodes NIN1+ and NIN1− are configured to serve as the D+ and D− inputs (not labeled) of flip-flop 500. Nodes NOUT1− and NOUT1− are coupled to nodes NIN2+ and NIN2−, respectively. Nodes NOUT2+ and NOUT2− serve as outputs Q+ and Q− (not labeled) for flip-flop 500, respectively. Nodes NCK1+ and NCK2+ are coupled together while nodes NCK1− and NCK2− are coupled together.

Each pair of transistors P13 and P14, and P23 and P24 acts as current sources and corresponds to the pair of current sources or transistors P3 and P4 of latch 100. In some embodiments, current sources P13 and P14 help speed up the Low to High transition of respective signals OUT1− and OUT1+ (or signal IN2+ and IN2−). Similarly, current sources P23 and P24 help speed up the Low to High transition of respective signals OUT2− and OUT2+. As a result, the operational frequency of flip-flop 500 is increased, i.e., the operational frequency of flip-flop 500 would be lower if flip-flop 500 does not include currents sources P13, P14, P23, and P24. In FIG. 5, two latches 100-1 and 100-2 are used, but various embodiments are not limited. A latch 100-1 or 100-2 may be replaced by a different latch, e.g., a latch 200, 300, or 400, etc.

### Frequency Divider

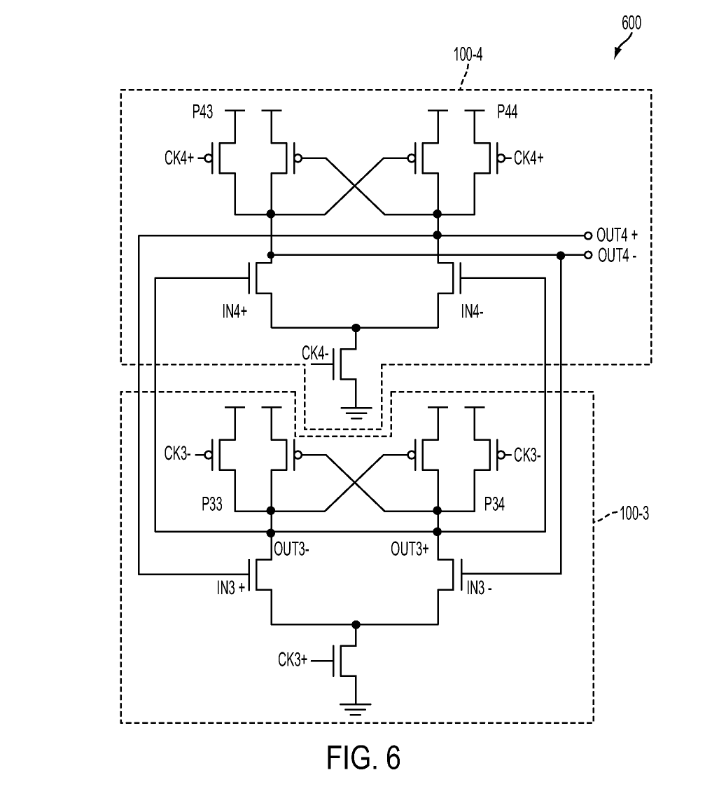

FIG. 6 is a diagram of a frequency divider 600, in accordance with some embodiments. Frequency divider 600 includes two latches 100, e.g., latch 100-3 and latch 100-4. For simplicity, only PMOS transistors P33, P34, P43, and P44 in frequency divider 600 are labeled. Latch 100-3 includes input nodes NIN3+, NIN3− (not labeled), output nodes NOUT3+ and NOUT3− (not labeled), and clock nodes NCK3+ and NCK3− (not labeled) corresponding to input nodes NIN+, NIN−, output nodes NOUT+ and NOUT−, and clock nodes NCK+ and NCK− of latch 100, respectively. Similarly, latch 100-4 includes input nodes NIN4+, NIN4− (not labeled), output nodes NOUT4+ and NOUT4− (not labeled), and clock nodes NCK4+ and NCK4− (not labeled) corresponding to input nodes NIN+, NIN−, output nodes NOUT+ and NOUT−, and clock nodes NCK+ and NCK− of latch 100, respectively.

Input nodes NIN3+ and NIN3− are configured to receive respective input signals IN3+ and IN3−. Clock nodes NCK3+ and NCK3− are configured to receive respective clock signals CK3+ and CK3−. Output nodes NOUT3+ and NOUT3− are configured to provide respective output signals OUT3+ and OUT3−. Similarly, input nodes NIN4+ and NIN4− are configured to receive respective input signals IN4+ and IN4−. Clock nodes NCK4+ and NCK4− are configured to receive respective clock signals CK4+ and CK4−. Output nodes NOUT4+ and NOUT4− are configured to provide respective output signals OUT4+ and OUT4−.

Nodes NIN3+ and NIN3− are coupled to respective nodes NOUT4+ and NOUT4− and serve as outputs of frequency divider 600. Nodes NOUT3− and NOUT3+ are coupled to nodes NIN4+ and NIN4−, respectively. Nodes NCK3+ and NCK4+ are coupled together while nodes NCK3− and NCK4− are coupled together. Nodes NCK3+ (and NCK4+) and NCK3− (and NCK4−) are configured to serve as the inputs of frequency divider 600.

Each pair of transistors P33 and P34, and P43 and P44 act as current sources and corresponds to the pair of current sources or transistors P3 and P4 of latch 100. In some embodiments, current sources P33 and P34 help speed up the Low to High transition of respective signals OUT3− and OUT3− (or signal IN4+ and IN4−). Similarly, current sources P43 and P44 help speed up the Low to High transition of respective signals OUT4− and OUT4+. As a result, the operational frequency of frequency divider 600 is increased, i.e., the operational frequency of frequency divider 600 would be lower if frequency divider 600 does not include currents sources P33, P34, P43, and P44. In FIG. 6, two latches 100-3 and 100-4 are used, but various embodiments are not so limited. A latch 100-3 or 100-4 may be replaced by a different latch, e.g., a latch 200, 300, or 400, etc.

### Exemplary Methods

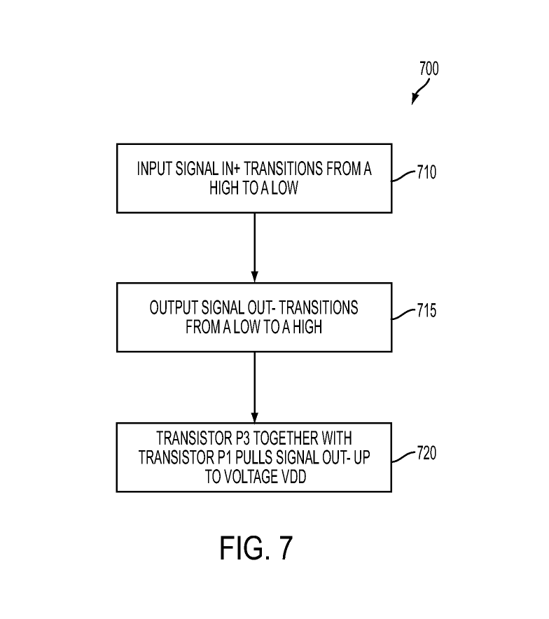

FIG. 7 is a flowchart 700 illustrating a method of operating latch 100, in accordance with some embodiments. For illustration, signal IN+ is High and signal OUT− is therefore Low, and clock CLK is on, i.e., signal CK+ is High and signal CK− is Low. Because signal CK− at the gate of transistor P3 is Low, transistor P3 is on.

In operation 710, signal IN+ transitions from a High to a Low.

In operation 715, as a result of signal IN+ transitioning from a High to a Low, signal OUT− transitions from a Low to a High.

In operation 720, transistor P3 being on, together with transistor P1, pulls signal OUT− up to voltage VDD faster than transistor P1 alone pulling up signal OUT−.

Transistor P4 pulls up signal OUT+ in a manner which is similar to transistor P3 pulling up signal OUT−. Transistors P3 and P4 in circuit 200 pulling up respective signals OUT− and OUT+ in circuit 200 is similarly performed as transistors P3 and P4 in circuit 100 pulling respective signals OUT− and OUT+ in circuit 100.

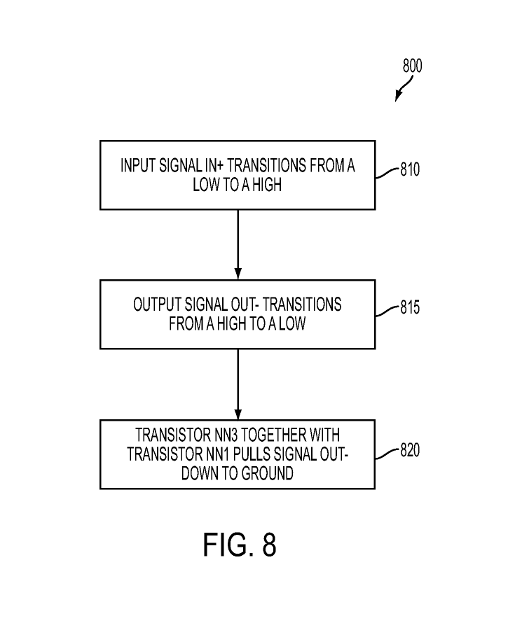

FIG. 8 is a flowchart 800 illustrating a method of operating circuit 300, in accordance with some embodiments. For illustration, signal IN+ is Low and signal OUT− is therefore High, and clock CLK is on, i.e., signal CK+ is High and signal CK−is Low. Because signal CK+ at the gate of transistor NN3 is High, transistor NN3 is on.

In operation 810, signal IN+ transitions from a Low to a High.

In operation 815, as a result of signal IN+ transitioning from a Low to a High, signal OUT− transitions from a High to a Low.

In operation 820, transistor NN3 being on, together with transistor NN1, pulls signal OUT− down to ground faster than transistor NN1 alone pulling down signal OUT−.

Transistor NN4 pulls down signal OUT+ in a manner which is similar to transistor NN3 pulling down signal OUT−. Transistors NN3 and NN4 in circuit 400 pulling respective signals OUT− and OUT+ in circuit 400 is similarly performed as transistors NN3 and NN4 pulling respective signals OUT− and OUT+ in circuit 300.

A number of embodiments have been described. It will nevertheless be understood that various modifications may be made without departing from the spirit and scope of the disclosure. For example, the various transistors being shown as a particular dopant type (e.g., N-type and P-type Metal Oxide Semiconductor or NMOS and PMOS) are for illustration purposes, embodiments of the disclosure are not limited to a particular type, but selecting different dopant types is within the scope of various embodiments. The logic level (e.g., Low or High) of the various signals used in the above description is also for illustration purposes, various embodiments are not limited to a particular level when a signal is activated and/or deactivated, but, selecting such a level is within the scope of various embodiments.

Some embodiments regard a latch circuit comprising: a cross latch circuit having a first node and a second node; a first transistor having a first first terminal, a first second terminal, and a first third terminal; a second transistor having a second first terminal, a second second terminal, and a second third terminal; a third transistor having a third first terminal, a third second terminal, and a third third terminal; a first current source; and a second current source. The first third terminal and the second third terminal are configured to receive a first input signal and a second input signal, respectively. The first node and the second node are configured to serve as a first output and a second output, respectively, for the latch circuit, and to have a first output signal and a second output signal. The first first terminal is coupled to the first node. The second first terminal is coupled to the second node. The third first terminal is coupled to the first second terminal and to the second second terminal. The first current source is coupled to the first node and is configured to affect a transition of the first output signal. The second current source is coupled to the second node and is configured to affect a transition of the second output signal.

Some embodiments regard a latch circuit comprising: a cross latch circuit having a first node and a second node; a first transistor having a first first terminal, a first second terminal, and a first third terminal; a second transistor having a second first terminal, a second second terminal, and a second third terminal; a third transistor having a third first terminal, a third second terminal, and a third third terminal; a first current providing transistor having a first transistor first terminal, a first transistor second terminal, and a first transistor third terminal; and a second current providing transistor having a second transistor first terminal, a second transistor second terminal, and a second transistor third terminal. The first third terminal and the second third terminal are configured to receive a first input signal and a second input signal, respectively. The first node and the second node are configured to serve as a first output and a second output, respectively, for the latch circuit, and to have a first output signal and a second output signal. The first first terminal is coupled to the first node. The second first terminal is coupled to the second node. The third first terminal is coupled to the first second terminal and to the second second terminal. The first transistor first terminal is coupled to the first node. The second current source is coupled to the second node. The first transistor third terminal and the second transistor third terminal are configured to receive a first clock signal. The third third terminal is configured to receive a second clock signal that is an inverse of the first clock signal.

Some embodiments regard a circuit comprising: a first latch, a first first current source, a first second current source, a second latch, a second first current source, and a second second current source. The first latch has a first first input and a first second input, a first first output and a first second output, a first first clock node and a first second clock node. The second latch has a second first input and a second second input, a second first output and a second second output, a second first clock node and a second second clock node. The first first output, the second first input, and the first first current source are coupled together. The first first current source is configured to affect a transition of the first first output and the second first input. The first second output, the second second input, and the first second current source are coupled together. The first second current source is configured to affect a transition of the first second output and the second first input. The second first current source is coupled to the second first output and is configured to affect a transition of the second first output. The second second current source is coupled to the second second output and is configured to affect a transition of the second second output.

The above methods show exemplary steps, but they are not necessarily performed in the order shown. Steps may be added, replaced, changed order, and/or eliminated as appropriate, in accordance with the spirit and scope of disclosed embodiments.

What is claimed is:

1. A latch circuit comprising:
a cross latch circuit having a first node and a second node;
a first transistor having a first first terminal, a first second terminal, and a first third terminal;
a second transistor having a second first terminal, a second second terminal, and a second third terminal;
a third transistor having a third first terminal, a third second terminal, and a third third terminal;
a first current source; and
a second current source;
wherein
the first third terminal and the second third terminal are configured to receive a first input signal and a second input signal, respectively.
the first node and the second node are configured to serve as a first output and a second output, respectively, for the latch circuit, and to have a first output signal and a second output signal;
the first first terminal is coupled to the first node;
the second first terminal is coupled to the second node;
the third first terminal is coupled to the first second terminal and to the second second terminal;
the first current source is coupled to the first node and is configured to affect a transition of the first output signal; and
the second current source is coupled to the second node and is configured to affect a transition of the second output signal.

2. The latch circuit of claim 1 wherein:
the first current source includes a fourth transistor having a fourth first terminal, a fourth second terminal, and a fourth third terminal;
the second current source includes a fifth transistor having a fifth first terminal, a fifth second terminal, and a fifth third terminal;
the fourth first terminal is coupled to the first node; and
the fifth first terminal is coupled to the second node.

3. The circuit of claim 1 wherein:
the first transistor, the second transistor, and the third transistor are NMOS transistors;
the cross latch is formed by a first PMOS transistor and a second PMOS transistor;
the first current source is configured to pull up the first output signal; and
the second current source is configured to pull up the second output signal.

4. The circuit of claim 3 wherein:
the first current source is a third PMOS transistor having a third PMOS drain, a third PMOS source, and a third PMOS gate;
the second current source is a fourth PMOS transistor having a fourth PMOS drain, a fourth PMOS source, and a fourth PMOS gate;
the third PMOS drain is coupled to the first node; and
the fourth PMOS drain is coupled to the second node;

5. The circuit of claim 4 wherein:
the third PMOS gate and the fourth PMOS gate are configured to receive a first clock signal; and
a gate of the third NMOS transistor is configured to receive a second clock signal being an inverse of the first clock signal.

6. The circuit of claim 1 wherein:
the first transistor, the second transistor, and the third transistor are PMOS transistors;
the cross latch is formed by a first NMOS transistor and a second NMOS transistor;
the first current source is configured to pull down the first output signal; and
the second current source is configured to pull down the second output signal.

7. The circuit of claim 6 wherein:
the first current source is a third NMOS transistor having a third NMOS drain, a third NMOS source, and a third NMOS gate;
the second current source is a fourth NMOS transistor having a fourth NMOS drain, a fourth NMOS source, and a fourth NMOS gate;
the third NMOS drain is coupled to first node; and
the fourth NMOS drain is coupled to the second node.

8. The circuit of claim 7 wherein:
the third NMOS gate and the fourth NMOS gate are configured to receive a first clock signal;
a gate of the third PMOS transistor is configured to receive a second clock signal being an inverse of the first clock signal.

9. The circuit of claim 1 wherein
the first current source and the second current source are configured to turn off when the third transistor is turned off.

10. The circuit of claim 9 wherein
the third transistor is turned off by a first clock signal;
the first current source and the second current source are turned off by a second clock signal being an inverse of the first clock signal.

11. A latch circuit comprising:
a cross latch circuit having a first node and a second node;
a first transistor having a first first terminal, a first second terminal, and a first third terminal;
a second transistor having a second first terminal, a second second terminal, and a second third terminal;
a third transistor having a third first terminal, a third second terminal, and a third third terminal;
a first current providing transistor having a first transistor first terminal, a first transistor second terminal, and a first transistor third terminal; and
a second current providing transistor having a second transistor first terminal, a second transistor second terminal, and a second transistor third terminal;
wherein
the first third terminal and the second third terminal are configured to receive a first input signal and a second input signal, respectively.
the first node and the second node are configured to serve as a first output and a second output, respectively, for the latch circuit, and to have a first output signal and a second output signal;
the first first terminal is coupled to the first node;
the second first terminal is coupled to the second node;
the third first terminal is coupled to the first second terminal and to the second second terminal;
the first transistor first terminal is coupled to the first node;
the second transistor first terminal is coupled to the second node;
the first transistor third terminal and the second transistor third terminal are configured to receive a first clock signal; and
the third third terminal is configured to receive a second clock signal that is an inverse of the first clock signal.

12. The circuit of claim 11 wherein:
the first transistor, the second transistor, and the third transistor are NMOS transistors;
the cross latch is formed by a first PMOS transistor and a second PMOS transistor;
the first current providing transistor is a PMOS transistor and is configured to pull up the first output signal; and
the second current providing transistor is a PMOS transistor and is configured to pull up the second output signal.

13. The circuit of claim 11 wherein:
the first transistor, the second transistor, and the third transistor are PMOS transistors;
the cross latch is formed by a first NMOS transistor and a second NMOS transistor;
the first current providing transistor is configured to pull down the first output signal; and
the second current providing transistor is configured to pull down the second output signal.

14. The circuit of claim 11 wherein
the first current providing transistor and the second current providing transistor are configured to turn off when the third transistor is turned off.

15. The circuit of claim 14 wherein the third transistor is turned off by the second clock signal.

16. A circuit comprising:
a first latch having
a first first input and a first second input;
a first first output and a first second output;
a first first clock node and a first second clock node;
a first first current source;
a first second current source;
a second latch having
a second first input and a second second input;
a second first output and a second second output;
a second first clock node and a second second clock node;
a second first current source; and
a second second current source;
wherein
the first first output, the second first input, and the first first current source are coupled together;
the first first current source is configured to affect a transition of the first first output and the second first input;
the first second output, the second second input, and the first second current source are coupled together;
the first second current source is configured to affect a transition of the first second output and the second second input;
the second first current source is coupled to the second first output and is configured to affect a transition of the second first output; and
the second second current source is coupled to the second second output and is configured to affect a transition of the second second output.

17. The circuit of claim 16 wherein:
the first first clock node is coupled to the second first clock node; and
the first second clock node is coupled to the second second clock node.

18. The circuit of claim 17 wherein:
the first clock node is configured to receive a first clock signal;
the second clock node is configured to receive a second clock signal that is an inverse of the first clock signal.

19. The circuit of claim 17 wherein:
the first first input is coupled to the second second output; and
the first second input is coupled to the second first output.

20. The circuit of claim 16 wherein:
the first first current source is a first first transistor having a first first drain;
the first second current source is a first second transistor having a first second drain;
the second first current source is a second first transistor having a second first drain;
the second second current source is a second second transistor having a second second drain;
the first first drain is coupled to the first first output;
the first second drain is coupled to the first second output;
the second first drain is coupled to the second first output; and
the second second drain is coupled to the second second output.
